(19) United States
(12) Patent Application Publication
(10) Pub. No.: US 2018/0212026 A1
(43) Pub. Date: Jul. 26, 2018

(54) SURFACE MODIFIED DIAMOND MATERIALS AND METHODS OF MANUFACTURING

(71) Applicant: Massachusetts Institute of Technology, Cambridge, MA (US)

(72) Inventors: Theodore H. Fedynyshyn, Sudbury, MA (US); Michael W. Geis, Acton, MA (US); Mark A. Hollis, Concord, MA (US)

(21) Appl. No.: 15/824,364

(22) Filed: Nov. 28, 2017

Related U.S. Application Data
(60) Provisional application No. 62/426,817, filed on Nov. 28, 2016.

(51) Int. Cl. H01L 29/16; C01B 32/28; B01J 19/12; C30B 29/04; C30B 33/00; H01L 21/02; H01L 21/04; H01L 29/10; H01L 29/08

(52) U.S. Cl. CPC H01L 29/1602; C30B 25/02; B01J 19/127; B01J 19/123; C30B 29/04; C30B 33/00; H01L 21/02527; H01L 21/0262; H01L 21/0405; H01L 29/1075; H01L 29/0843; C01P 2006/40; B01J 2219/1203; B01J 2219/0879; C01B 32/28

(57) ABSTRACT

New compositions of matter and device constructs are disclosed in the form of diamond material layers or films having one or more surfaces treated with chemically active radicals, e.g., photo-radical or thermal-radical generators to reduce and stabilize their surface resistance. The compositions exhibit stable, markedly lower surface resistances, e.g., below about 3 kΩ sq⁻¹ or between about 3 and 2 kΩ sq⁻¹ or below 2 kΩ sq⁻¹, or below 1 kΩ sq⁻¹, or lower. In certain embodiments, the diamond material is a epitaxial layer grown on a substrate, e.g., by microwave plasma chemical vapor deposition (CVD) and can have a thickness ranging from about 1 nm to 1 mm, preferably from about 10 nm to 500 μm, or from about 100 nm to 10 μm. The invention also encompasses semiconductor devices fabricated from the surface-modified diamond materials disclosed herein. For example, device can be a field effect transistor in which the diamond material provides a hole conductivity channel between a source region and a drain region that is activated by a voltage applied to an intermediate gate region. Methods are also disclosed for modifying diamond surfaces to decrease and stabilize their surface resistance.

### REFERENCE TO RELATED APPLICATION

This application claims priority to U.S. Provisional Patent Application No. 62/426,817 of the same title filed Nov. 28, 2016, herein incorporated by reference in its entirety.

### GOVERNMENT RIGHTS

This invention was made with Government support under Contract No. FA8721-05-C-0002 awarded by the U.S. Air Force. The Government has certain rights in the invention.

### BACKGROUND

Diamond, as a material, has a larger room temperature thermal conductivity and a higher break down voltage than any current device quality semiconductor. Because of these two properties, diamond field effect transistors (FETs) have the potential to outperform FETs made in any other semiconductor. But the performance of diamond FET's is currently limited by large and unstable surface electrical resistances. Presently, FETs made of diamond have surface resistance from about 5 to 10 kΩ sq⁻¹ while FETs fabricated in AlGaN/GaN, the highest performing FETs at present, have a much lower effective surface resistance, e.g., from about 0.3 to 0.4 kΩ sq⁻¹.

Various efforts have been made to reduce diamond surface resistance by modifying the surface. The lowest diamond surface resistance observed to date has been 1-2 kΩ sq⁻¹ and was obtained by treating hydrogen-terminated diamond surface with NO₂. However, this resistance is unstable. Often the resistance doubles within an hour after treatment and in less than a day the resistance can be greater than 4 kΩ sq⁻¹.

Lowering the surface resistance is the same as increasing surface conductance. Having increased conductance that is stable over time is crucial to the development of diamond-based transistors and the devices that can be made from diamond-based transistors. Thus, there exists a need for practical methods of producing stable, higher conductivity, diamond surfaces. Surface modified diamond materials exhibiting higher conductivity would be satisfy a long-felt need in diamond transistor technology with wide applicability to electronic devices.

### SUMMARY

New compositions of matter and device constructs are disclosed in the form of diamond material layers or films having one or more surfaces modified to stabilize surface resistance. Such modification can be achieved by application of chemically active radicals. In certain embodiments, the modifying radical can be, for example, an azo radical, benzoyl radical, a phosphineoxide benzoyl radical, peroxyl radical, or an azide radical. In certain embodiments, the surface-modifying radical employ an intermediate nitrene to form an amine on the diamond surface. In certain embodiments, the diamond surface can be treated with a radical generator, such as a photo radical initiator or a thermal radical initiator.

The compositions exhibit stable, markedly lower surface resistances, e.g., below about 3 kΩ sq⁻¹ or between about 3 and 2 kΩ sq⁻¹ or below 2 kΩ sq⁻¹, or below 1 kΩ sq⁻¹, or lower. In certain embodiments, the diamond material is a epitaxial layer grown on a substrate, e.g., by microwave plasma chemical vapor deposition (CVD) and can have a thickness ranging from about 1 nm to 1 mm, preferably from about 10 nm to 500 μm, or from about 10 nm to 10 μm.

The invention also encompasses semiconductor devices fabricated from the surface-modified diamond materials disclosed herein. For example, device can be a field effect transistor in which the diamond material provides a hole conductivity channel between a source region and a drain region that is activated by a voltage applied to an intermediate gate region.

Methods are also disclosed for modifying diamond surfaces to decrease and/or stabilize their surface resistance. In one aspect of the invention, the method can be practiced by treating diamond surfaces with chemically active radicals to lower the surface resistance in a manner that is stable over time. The methods of the present invention can produce stable, markedly lower surface resistances.

In certain embodiments, the method can include a first step of converting the diamond to one with hydrogen (H) surface terminations. Any method to create hydrogen termination on the diamond surface is acceptable for the initial modification of the diamond surface. One preferred method of producing a hydrogen-terminated surface is to expose the diamond to a hydrogen plasma, which removed any oxygen on the diamond surface and terminated the carbon surface with H atoms.

The hydrogen terminated diamond surface can then be treated with a radical generator either as a film or in solution. Free radicals are generated either photolytically or thermally and the free radical displaces hydrogen on the diamond surface to produce a diamond surface modified with an organic moiety. To generate radicals photolytically, the diamond can be exposed to actinic radiation in the presence of the radical generator. The actinic radiation, for example, can be radiation having one or more wavelengths between 150 to 800 nm. In certain embodiments the actinic radiation can be ultraviolet radiation, e.g., between 200 and 400 nm. The time of exposure is dependent on the absorbance of the radical generator, the energy of the exposure source, and the amount of surface modification required. Any time period sufficient to generate radicals in sufficient quantity to modify the surface is acceptable in performing the invention.

If the radicals are generated thermally, the diamond in the presence of the radical generator is heated to any temperature required to thermally decompose the radical generator. The time and temperature of exposure is dependent on the thermal decomposition rate of the radical generator and the amount of surface modification required. Any time period sufficient to generate radicals in sufficient quantity to modify the surface is acceptable in performing the invention.

In some instances the radical generator produces a radical in which the free electron is centered on a carbon atom, the carbon atom having any number of other atoms attached to it. It is less preferred that the free electron be centered on an oxygen atom. The radical need not remain associated with the diamond surface. In certain embodiments, the treatment need only sustain a negative charge at the treated surface and a positive charge in the bulk of the material. Without being bound by any theory or mechanism of action, the radical may serve to remove some of the hydrogen present on the diamond surface and cause the superficial carbon atoms to form double bonds with each other, e.g., other carbon atoms in the lattice.

Further understanding of various aspects of the invention can be obtained by reference to the following detailed description in conjunction with the associated drawings, which are described below.

### DESCRIPTION OF THE DRAWINGS

The present disclosure is described with reference to the following figures, which are presented for the purpose of illustration only and are not intended to be limiting.

FIG. 1 is a flow diagram illustrating a method of modifying a surface of a diamond material such as to decrease the resistance according to the invention;

FIG. 2 is a schematic, cross-section view of a semiconductor device according to the invention employing a treated diamond material according to the invention;

FIG. 3 is a graph of surface resistance versus time (minutes) for a diamond surface treated with a radical generator according to the invention and comparative data for a diamond surface treated by a conventional NO₂ approach;

FIG. 4 is a graph of surface resistance versus time (days) for a diamond surface treated with various radical generators according to the invention demonstrating stability over time;

FIG. 4A is a diagram of the chemical structure of a radical generator (Darocur® 890) according to the invention;

FIG. 4B is a diagram of the chemical structure of another radical generator (Darocur® TPO-L) according to the invention;

FIG. 4C is a diagram of the chemical structure of another radical generator (Darocur® TPO) according to the invention;

FIG. 4D is a diagram of the chemical structure of another radical generator (Ingacure® 784) according to the invention;

FIG. 4E is a diagram of the chemical structure of another radical generator (Ingacure® 1173) according to the invention;

FIG. 4F is a diagram of the chemical structure of another radical generator (Ingacure® 184) according to the invention;

FIG. 4G is a diagram of the chemical structure of another radical generator (Ingacure® 651) according to the invention;

FIG. 4H is a diagram of the chemical structure of another radical generator (Ingacure® 369) according to the invention;

FIG. 4I is a diagram of the chemical structure of another radical generator (Aryl bisdiazide) according to the invention.

FIG. 5A is a depiction of laser or optical beam exposing the surface of a diamond FET;

FIG. 5B illustrates how mobile holes in the diamond are attracted to the formed modification on the diamond surface of FIG. 5A, and

FIG. 5C illustrates that the charge groups can be formed non-uniformly on the drain side of the FET shown in FIG. 5A.

### DETAILED DESCRIPTION

As noted above, the invention provides methods to modify a surface of a diamond material such as to decrease the surface resistance. The modification can be performed by first converting the diamond to one with hydrogen surface terminations. Any method to create hydrogen termination on the diamond surface is acceptable for the initial modification of the diamond surface. One preferred method of producing a hydrogen-terminated surface is to expose the diamond to a H plasma, which removed any oxygen on the diamond surface and terminated the carbon surface with H atoms.

The hydrogen terminated diamond surface is then treated with a radical generator either as a film or in solution. Free radicals are then generated either photolytically or thermally and the free radical displaces hydrogen on the diamond surface to produce a diamond surface modified with an organic moiety.

Without being bound to any theory, the radical associated with the diamond surface can further react or be lost in a manner that at least some of the superficial carbon atoms form double bounds with each other, e.g., other carbon atoms in the lattice.

In one embodiment, the diamond surface can be modified by an alkyl or aromatic group in which the carbon of the modifying group is attached to the diamond. Diamond surface modification with azo radical generators is shown schematically below:

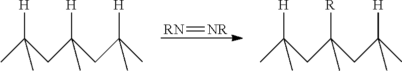

In another embodiment, the diamond surface can be modified by an alkyl or aromatic benzoyl group in which the carbon bearing a ketone of the modifying group is attached to the diamond. Diamond surface modification with benzoyl radical generators are shown schematically below:

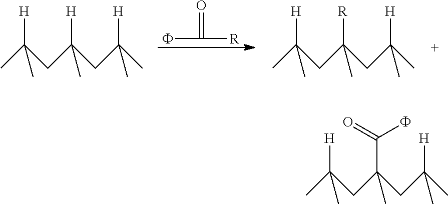

In yet another embodiment, the diamond surface can be modified by an alkyl or aromatic benzoyl group attached to a phosphorous or phosphineoxide which the phosphorous bearing the alkyl or aromatic group of the modifying group is attached to the diamond. Diamond surface modification with phosphineoxide benzoyl radical generators are shown schematically below:

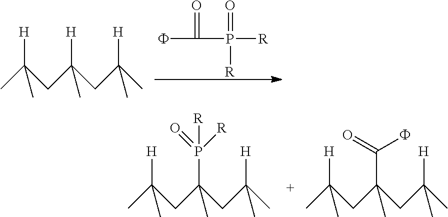

In yet another embodiment, the diamond surface can be modified by an alkyl or aromatic carboxyl group in which the oxygen of the modifying group is attached to the diamond. Diamond surface modification with peroxide generators are shown schematically below:

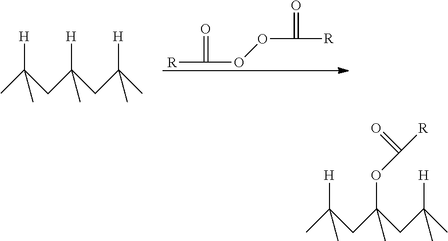

Additional examples of thermal radical initiators that produce radical in which the free electron is centered on a carbon atom are diazonium salts noting that the thermal reaction may proceed at room temperate and not require heating. Diamond surface modification with diazonium radical generators are shown schematically below:

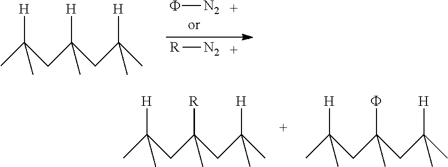

Another method to modify the diamond surface is by the addition of a nitrogen containing moiety onto the diamond surface. This can be accomplished by the insertion of a nitrene between the carbon and hydrogen bond or by a free radical addition process. The nitrene may be formed by either the photolytic or thermal decomposition of an azide. It is preferred that the nitrene be formed adjacent to an aromatic ring or a carbonyl containing moiety or a sulfonyl containing moiety.

The diamond surface can also be modified by an alkyl or aromatic carboxyl group in which the nitrogen of the modifying group is attached to the diamond. Diamond surface modification with azide radical generators is shown schematically below:

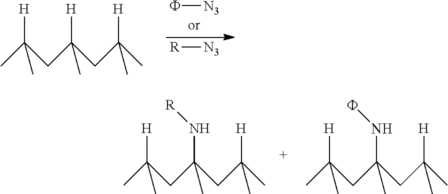

As previously noted, in each of the examples described above, the radical associated with the diamond surface can further react or be lost in a manner that at least some of hydrogen terminations are removed and hydrogen-free superficial carbon atoms form double bounds with other carbon atoms in the lattice. Again, without being bound to any particular theory, superficial double bonds between carbon atoms may formed as the result of radical (and hydrogen) liberation from the surface, These double bonds may present fullerene-like structures at the diamond surface that can sustain a superficial negative charge while trapping positive charges in the diamond substrate bulk.

Not wishing to be bound by any particular theory, during the modification of the diamond surface the first presumed step is generation of a radical species either photolytically or thermally from the radical generator followed by removal of a diamond surface hydrogen by the generated radical to yield a neutral species as shown in Path A. The diamond surface radical can then combine with a second photolytically or thermally generated radical to form a modified surface through a substitution reaction as shown in Path B. It is also possible that a second photolytically or thermally generated radical could remove a second hydrogen on the diamond surface leading to two radicals on the diamond surface as shown in Path C. The two diamond surface radicals can combine to form a modified surface through the formation of a surface double bond. The surface double bonds can combine to form a conjugated structure or a fullerene-link structure. Either or both Path B and C can occur to various degrees after the initial loss of surface hydrogen that can occur via Path A.

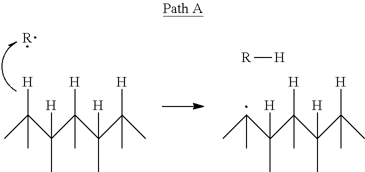

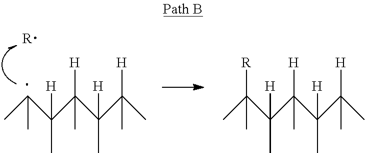

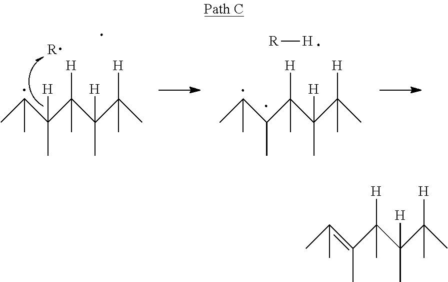

Examples of photo-radical generators (available from Ciba) include are 1-Hydroxycyclohexyl phenyl ketone (Irgacure 184), 2-Benzyl-2-dimethylamino-1-(4-morpholinophenyl)-butanone-1 (Irgacure 369), cyclopenta-1,3-diene; 1-(2,4-difluorocyclohexa-2,3,5-trien-1-yl)pyrrole; titanium (Irgacure 784), bis(2,4,6-trimethylbenzoyl)-phenylphosphineoxide (Irgacure 819), 2-hydroxy-2-methyl-1-phenyl-propan-1-one (Darocure 1173), 2,4,6-trimethylbenzoyl-diphenyl-phosphineoxide (Darocur TPO), ethyl (2,4,6-trimethylbenzoyl) phenylphosphinate (Darocur TPO-L), 50% 1-hydroxy-cyclohexyl-phenyl-ketone and 50% benzophenone (Irgacure 500), Oxy-phenyl-acetic acid 2-[2-oxo-2-phenyl-acetoxy-ethoxy]-ethyl ester and Oxy-phenyl-acetic acid 2-[2-hydroxy-ethoxy]-ethyl ester (Irgacure 754), 2-Methyl-1[4-(methylthio)phenyl]-2-morpholinopropan-1-one (Irgacure 907, methylbenzoylformate (Darocur MBF), 30% 2-Benzyl-2-dimethylamino-1-(4-morpholinophenyl)-butanone-1 and 70% 2,2-Dimethoxy-1,2-diphenylethan-1-one (Irgacure 1300), 50% diphenyl (2,4,6-trimethylbenzoyl)-phosphine oxide and 50% 2-Hydroxy-2-methyl-1-phenyl-1-propanone (Darocur 4465), phosphine oxide, phenyl bis (2,4,6-trimethyl benzoyl) (Irgacure 819W, 20% bis(2,4,6-trimethylbenzoyl)-phenylphosphineoxide and 80% 2-hydroxy-2-methyl-1-phenyl-propan-1-one (Irgacure 2022), iodonium, (4-methylphenyl) [4-(2-methylpropyl) phenyl]-, hexafluorophosphate(1-) (Irgacure 250), mixture of ethyl (2,4,6-trimethylbenzoyl) phenylphosphinate and 2,4,6-trimethylbenzoyl-diphenyl-phosphineoxide (Irgacure 2100), benzophenone (Darocur BP), Irgacure 2100, Irgacure 261, Irgacure 379, Irgacure 651, Irgacure 727, Irgacure 750, Irgacure 907, Irgacure 1035, Irgacure 1700, Irgacure 1800, Irgacure 2959, Irgacure OXE01, Darocur 4265, Darocur TPO, CGI 1905, and CGI 263.

Additional examples of photo-radical generators are acetophenone, anisoin, anthraquinone, anthraquinone-2-sulfonic acid, sodium salt monohydrate, (benzene) tricarbonylchromium, benzil, benzoin, benzoin ethyl ether, benzoin isobutyl ether, benzoin methyl ether, benzophenone, 50/50 blend of benzophenone/1-hydroxycyclohexyl phenyl ketone, 3,3′,4,4′-benzophenonetetracarboxylic dianhydride, 4-benzoylbiphenyl, 2-benzyl-2-(dimethylamino)-4′-morpholinobutyrophenone, 4,4′-bis(diethylamino)benzophenone, 4,4′-bis(dimethylamino)benzophenone, camphorquinone, 2-chlorothioxanthen-9-one, 4,4′-dihydroxybenzophenone, 2,2-Dimethoxy-2-phenylacetophenone, 4-(dimethylamino)benzophenone, 4,4′-dimethylbenzil, 2,5-dimethylbenzophenone, 3,4-dimethylbenzophenone, 50/50 blend of diphenyl(2,4,6-trimethylbenzoyl)phosphine oxide/2-hydroxy-2-methylpropiophenone, 4′-ethoxyacetophenone, 2-ethylanthraquinone, ferrocene, 3′-hydroxyacetophenone, 4′-hydroxyacetophenone, 3-hydroxybenzophenone, 4-hydroxybenzophenone, 1-hydroxycyclohexyl phenyl ketone, 2-hydroxy-2-methylpropiophenone, 2-methylbenzophenone, 3-methylbenzophenone, methybenzoylformate, 2-methyl-4′-(methylthio)-2-morpholinopropio-phenone, phenanthrenequinone, 4′-phenoxyacetophenone, thioxanthen-9-one, 4-methyl benzophenone, 2-isopropylthioxanthone, 2-hydroxy-2-methyl-1-phenyl-1-propanone, and camphorquinon.

Photo-radical generators can also include chemicals that are employed as photo-acid generators noting that these materials produce radicals prior to generating the photo acid and as such can act as photo-radical generators within the scope of this invention.

Examples of suitable photo-acid generators include onium salts, such as triphenylsulfonium salts, sulfonium salts, iodonium salts, diazonium salts and ammonium salts, 2,6-nitrobenzylesters, 1,2,3-tri(methanesulfonyloxy)benzene, sulfosuccinimides and photosensitive organic halogen compounds as disclosed in Japanese Examined Patent Publication No. 23574/1979. Other examples of suitable photo-acid generators are (cumene)cyclopentadienyliron(II), hexafluorophosphate, dibenzosuberenone, 2,2-diethoxyacetophenone, triarylsulfonium hexafluoroantimonate, and triarylsulfonium hexafluorophosphate.

Specific examples of diphenyliodonium salts include diphenyliodonium triflate (DPI-105, Midori Kagaku Co. Ltd.), di-t-butylphenyl iodonium perfluorobutyl sulfonate (Toyo Gosei Kogyo Co., Ltd.), and diphenyliodonium tosylate (DPI-201, Midori Kagaku Co. Ltd.). Examples of suitable bis(4-tert-butylphenyl)iodonium salts include bis(4-tert-butylphenyl)iodonium triflate (BBI-105, Midori Kagaku Co. Ltd.), bis(4-tert-butylphenyl)iodonium camphorsulfate (BBI-106, Midori Kagaku Co. Ltd.), bis(4-tert-butylphenyl)iodonium perfluorbutylate (BBI-109, Midori Kagaku Co. Ltd.) and bis(4-tert-butylphenyl)iodonium tosylate (BBI-201, Midori Kagaku Co. Ltd.). Suitable examples of triphenylsulfonium salts include triphenylsulfonium hexafluorophosphite (TPS-102, Midori Kagaku Co. Ltd.), triphenylsulfonium triflate (TPS-105, Midori Kagaku Co. Ltd.), triphenylsulfonium perfluorobutylate (TPS-109, Midori Kagaku Co. Ltd.), and triphenylsulfonium perfluorobutyl sulfonate (Toyo Gosei Kogyo Co., Ltd.).

Specific examples of photo-acid generating organic halogen compounds include halogen-substituted paraffinic hydrocarbons such as carbon tetrabromide, iodoform, 1,2,3,4-tetrabromobutane and 1,1,2,2-tetrabromoethane; halogen-substituted cycloparaffinic hydrocarbons such as hexabromocyclohexane, hexachlorocyclohexane and hexabromocyclododecane; halogen-containing triazines such as tris(trichloromethyl)-s-triazine, tris(tribromomethyl)-s-triazine, tris(dibromomethyl)-s-triazine, perhalomethyl triazines, and 2,4-bis(tribromomethyl)-6-methoxyphenyl-s-triazine; halogen-containing benzenes such as (bis(trichloromethyl)benzene and bis(tribromomethyl)benzene; halogen-containing sulfone compounds such as tribromomethylphenylsulfone, trichloromethylphenylsulfone and 2,3-dibromosulforane; and halogen-substituted isocyanurates such as tris(2,3-dibromopropyl)isocyanurate. Alsomong such photolytically-sensitive organic halogen compounds, a bromine-containing compound, such as bromobisphenol A, can also be utilized.

Examples of thermal radical initiators that produce radical in which the free electron is centered on a carbon atom, the carbon atom having any number of other atoms attached to it. It is more preferred that the free electron be centered on the carbon and less preferred that the free electron is centered on an oxygen atom. Examples are 4,4′-Azobis(4-cyanovaleric acid), 1,1′-Azobis(cyclohexanecarbonitrile), Azobisisobutyronitrile, 2,2′-Azobis(2-methylpropionamidine).

Additional examples of thermal radical initiators that produce radical in which the free electron is centered on a carbon atom are diazonium salts noting that the thermal reaction may proceed at room temperate and not require heating. Examples of diazonium salts are 4-(Diazonium)benzenesulfonic acid tetrafluoroborate, 4-nitrobenzenediazonium tetrafluoroborate, 4-bromobenzenediazonium tetrafluoroborate, 4-chlorobenzenediazonium tetrafluoroborate, 4-fluorobenzenediazonium tetrafluoroborate, 4-iodobenzenediazonium tetrafluoroborate, 4-methoxybenzenediazonium tetrafluoroborate, 3,5-Dichlorophenyldiazonium, tetrafluoroborate, Benzenediazonium hexafluorophosphate, 4′-Nitro-1,1-biphenyl-4-diazonium tetrafluoroborate, and 2,5-Dibutoxy-4-(4-morpholinyl)benzenediazonium tetrafluoroborate.

It is preferred that the radical generator produce a radical in which the free electron is centered on a carbon atom, the carbon atom having any number of other atoms attached to it. It is less preferred that the free electron is centered on an oxygen atom.

Examples of thermal radical initiators that produce radical in which the free electron is centered on an oxygen atom. Examples are tert-Butyl hydroperoxide, tert-Butyl peracetate, Cumene hydroperoxide, 2,5-Di(tert-butylperoxy)-2,5-dimethyl-3-hexyne, Dicumyl peroxide, Luperox® 101, 2,5-Bis(tert-butylperoxy)-2,5-dimethylhexane, Luperox® 101XL45, 2,5-Bis(tert-butylperoxy)-2,5-dimethylhexane, blend with calcium carbonate and silica, Luperox® 224, 2,4-Pentanedione peroxide, Luperox® 231, 1,1-Bis(tert-butylperoxy)-3,3,5-trimethylcyclohexane, Luperox® 331M80, 1,1-Bis(tert-butylperoxy)cyclohexane, Luperox® 531M80, 1,1-Bis(tert-amylperoxy)cyclohexane, Luperox® A70S, Benzoyl peroxide, Luperox® A75, Benzoyl peroxide, Luperox® A75FP, Benzoyl peroxide, Luperox® A98, Benzoyl peroxide, Luperox® AFR40, Benzoyl peroxide, Luperox® ATC50, Benzoyl peroxide, Luperox® DDM-9, 2-Butanone peroxide, Luperox® DHD-9, 2-Butanone peroxide, Luperox® DI, tert-Butyl peroxide, Luperox® LP, Lauroyl peroxide, Luperox® P, tert-Butyl peroxybenzoate, Luperox® TBEC, tert-Butylperoxy 2-ethylhexyl carbonate, Luperox® TBH70X, and tert-Butyl hydroperoxide.

Modifying the diamond surface by the addition of a nitrogen containing moiety onto the diamond surface can be accomplished by the insertion of a nitrene between the carbon and hydrogen bond or by a free radical addition process. The nitrene may be formed by either the photolytic or thermal decomposition of an azide. In certain embodiments, the nitrene can be formed adjacent to an aromatic ring or a carbonyl containing moiety or a sulfonyl containing moiety.

If the radicals are generated photolytically, the diamond in the presence of the radical generator can be exposed to actinic radiation between 150 to 800 nm although the more preferred range is between 200 and 400 nm. The time of exposure is dependent on the absorbance of the radical generator, the energy of the exposure source, and the amount of surface modification required. Any time period sufficient to generate radicals in sufficient quantity to modify the surface is acceptable in performing the invention.

If the radicals are generated thermally, the diamond in the presence of the radical generator is heated to any temperature required to thermally decompose the radical generator. The time and temperature of exposure is dependent on the thermal decomposition rate of the radical generator and the amount of surface modification required. Any time period sufficient to generate radicals in sufficient quantity to modify the surface is acceptable in performing the invention.

Examples of azides that would produce nitrenes are 2,6-Bis-(4-azido-benzylidene)-4-methyl-cyclohexanone (ABD) by TCI Chemicals, 2,6-Bis-(4-azido-benzylidene)-4-methyl-cyclohexanone, 1-Azido-2-bromobenzene, 1-Azido-3-bromobenzene, 1-Azido-4-bromobenzene, 1-Azido-2-chlorobenzene, 1-Azido-3-chlorobenzene, 1-Azido-4-chlorobenzene, 1-Azido-2-fluorobenzene, 1-Azido-3-fluorobenzene, 1-Azido-4-fluorobenzene, 1-Azido-3-iodobenzene, 1-Azido-4-iodobenzene, 4-azido-2-nitrophenol, Azidobenzene, 4-Azidoaniline hydrochloride, 4-Azido-2,3,5,6-tetrafluorobenzoic acid, 1-Azido-2-(trifluoromethyl)benzene, 1-Azido-3-(trifluoromethyl)benzene, 1-Azido-4-(trifluoromethyl)benzene, 4-Azidophenyl isothiocyanate, 4-Azidophenyl, Benzoyl azide, 2-Azidobenzoic, 4-Azidobenzoic acid, 4-Carboxybenzenesulfonazide, 1-(Azidomethyl)-4-bromobenzene, 1-(Azidomethyl)-2-chlorobenzene, 1-(Azidomethyl)-4-chlorobenzene, 1-(Azidomethyl)-2-fluorobenzene, 1-(Azidomethyl)-4-fluorobenzene, 2-Azidotoluene, 3-Azidotoluene, 4-Azidotoluene, 2-Azidoanisole, 3-Azidoanisole, 4-Azidoanisole, p-Toluenesulfonyl azide, 4-azidobenzohydrazide, 4-Azidophenacyl bromide, p-Azidoacetophenone, Methyl 2-azidobenzoate, Methyl 3-azidobenzoate, Methyl 4-azidobenzoate, 4-Acetamidobenzenesulfonyl azide, 3-(4-Azidophenyl)propionic acid, 4-Methoxybenzyloxycarbonyl azide, 2-azido-1-methylquinolinium tetrafluoroborate, 2-azido-1-ethylquinolinium tetrafluoroborate, 4-(4-azido salicylamido)butylamine, 2,4,6-Triisopropylbenzenesulfonyl azide, 2,4,6-Triisopropylbenzenesulfonyl azide, and 4-Dodecylbenzenesulfonyl azide.

A sensitizer can be added to the film or solution of the photolytic radical or nitrene generators to increase the absorbance of the material and by energy transfer to the radical or nitrene generators and thereby increase amount of radicals or nitrenes generated and thus increase the sensitivity of the material toward photons. Any sensitizer can be chosen from those that are known in the art. Specific examples of sensitizers are UVS-1101, UVS-1221, and UVS-1331 from Kawasaki Kasei Chemcials Ltd.

The terms “long term” and “stable” as used herein to describe surface resistance or surface conductivity are intended to denote a consistency of measure values over a time of at least a day or least a week. Typically, fluctuation in surface resistance or surface conductivity of modified diamond surfaces manifest themselves in hours following convention treatments. Conversely, resistance or conductivity values that are consistent when measured over a period of more than a day, several days or a week are likely to remain that way permanently.

The surface resistance of a FET adversely affects the device performance, power gain, frequency response and power efficiency. As noted above, previous approaches to diamond surface stabilization have resulted in unacceptably high resistance of 5 to 10 kΩ sq⁻¹. The approach outlined here results in a lower resistance of 2 to 3 kΩ sq⁻¹ or lower. However the general concept of radical surface chemistry allows for variety of diamond surface chemistries that may further reduce the surface resistance

A reduced and stable surface resistance allows for the fabrication of diamond FETs where they can replace the present state of the art AlGaN/GaN FETs for power radio frequency (RF) amplifiers by virtue of diamond's higher break down voltage and thermal conductivity. If the surface resistivity is decreased to less than 1 kΩ sq⁻¹, the potential exists for power converters useful in a national power grid.

Whether for analog or digital applications, it is generally desirable to reduce the source resistance of field-effect transistors (FETs) as low as possible. Doing so minimizes the compression of the device's transconductance, thereby enhancing the gain, switching speed, and high-frequency performance. Common semiconductor fabrication techniques are limited in reducing source resistance as they typically use semiconductor layers that are uniformly doped or have a uniform density of charge carriers across their planar extent, and therefore cannot easily reduce the resistance of the semiconductor material beyond the edge of the source ohmic contact, which is typically metallic.

Ideally one would like to have a heavier carrier density nearer the source ohmic contact and gradually reduce it in the semiconductor channel as the gate is approached. Such a non-uniform density of charge is very difficult or impossible to achieve with traditional fabrication methods, but since the diamond surface can be modified through the use of photo-generated radicals, it is possible to use a focused light source or laser beam to selectively create photo-generated radicals in only selected areas of the diamond such that the diamond surface is only modified in selected areas where the light was applied and the photo-radicals generated. The light source or laser beam can be focused into a small spot size and the diamond surface imaged either directly or the surface can be imaged with the light passing through a mask that allows light to penetrate only in selective areas. One skilled in the art can employ exposure techniques that allow imaging with resolution down to 100 nm and even down to 20 nm or even lower.

The amount of photo-radicals generated is a direct function of the photon flux and thus the amount of photo-radicals generated can be controlled by the amount of photon flux on the surface. The degree of surface modification can controlled by the amount of photo-radicals generated allowing the degree of surface modification to be controlled by the amount of photon flux on the surface. The photon flux will therefore define the carrier density and allow different carrier density to be imparted by changing the amount of light energy on the surface.

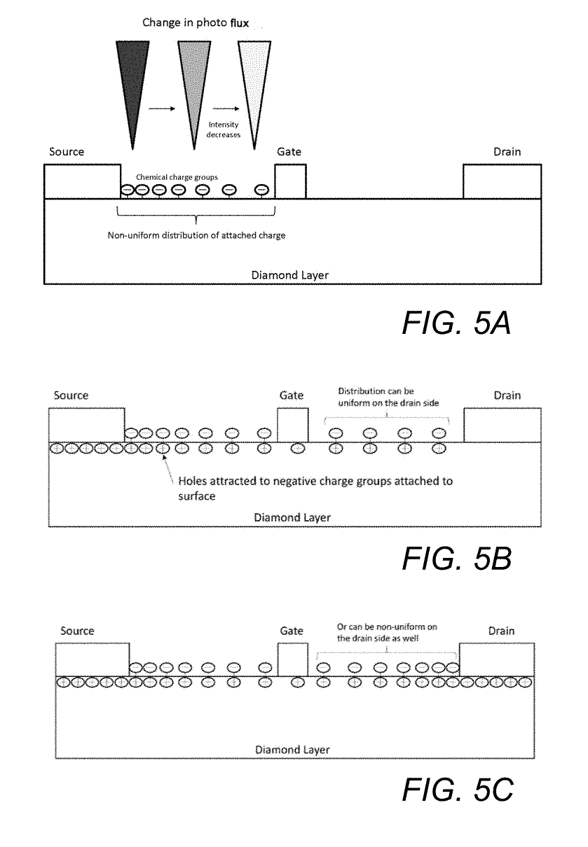

An example of a change in photon flux at the diamond surface affecting the properties of the diamond surface to give a non-uniform density is shown in FIG. 5A. In this figure it is assumed that a photo-radical generator is in proximity to the diamond surface being exposed. The non-uniform density may be achieved by changing photon flux per unit area as exposure dose decreases toward the gate. As shown in FIG. 5B, the resulting presence of the non-uniformly distributed attached charge groups causes mobile hole charges in the diamond to be attracted to the attached charges, thereby forming a conducting transistor channel which has excess hole carriers nearer the source contact for lower source resistance. This same method may be applied to the drain side of the diamond channel to reduce the drain resistance as well, as depicted in FIG. 5C. Even though the attached charge groups depicted here are negative and the mobile carriers are holes, this invention is by no means limited to this charge combination, as other charge groups can be attached which are positive and which would give rise to, and/or attract, electrons as the mobile carriers.

In another embodiment of this direct-write technique, one can use a laser or other photolithographic tool such as a stepper or contact aligner to expose small patches of the surface that are coated or in close proximity to the photo-radical generator. The exposure area will have the diamond surface modified thereby defining the areas where FETs and their channels will be made, leaving the rest of the diamond surface un-modified and insulating. This could be very advantageous for integrated-circuit manufacturing, as certain areas could be patterned for diamond FETs and other areas left for the fabrication of other kinds of devices on the surface including capacitors, inductors, resonators, and resistors. Laser direct writing also allows rapid reconfiguration of circuit layouts without having to fabricate new photomasks.

Optical wavelengths that may be useful for such direct writing include any actinic wavelength between 150 and 800 nm with a more preferred wavelength range of between 150 and 450 nm. Specific wavelengths of light that may be particularly useful are 157, 193, 248, 256, 365, 405, and 436 nm.

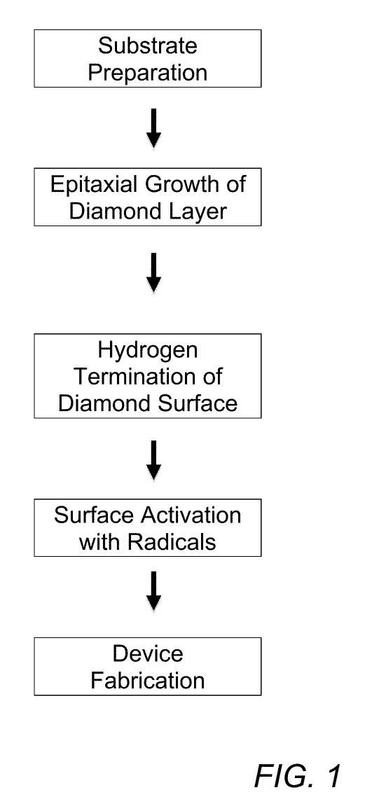

FIG. 1 is a flow diagram illustrating a method of modifying a surface of a diamond material such as to decrease the resistance according to the invention. First, a suitable substrate is prepared to accept deposition of diamond material. Second, diamond is deposited by any suitable method, such a microwave plasma chemical vapor deposition. The diamond material is preferably formed as a single crystal layer. Third, the diamond surface can be prepared by hydrogen termination, e.g., by heating the diamond surface in a gas mixture containing hydrogen and an inert carrier. Fourth, the hydrogen terminated surface is treated with a radical generator such that the terminal hydrogen atoms are replace with chemical radicals. The modified surface can then be incorporated into a semiconductor device

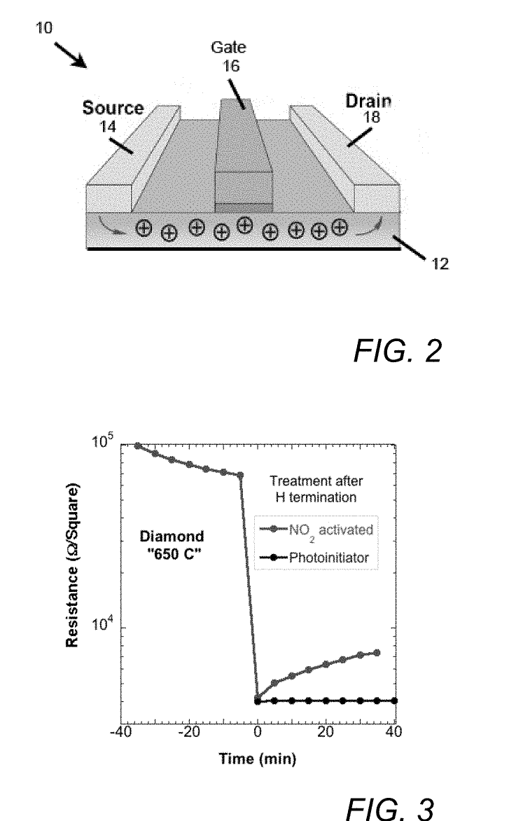

FIG. 2 is a schematic, cross-section view of such a semiconductor device according to the invention incorporating a surface-modified diamond material. The device 10 includes a surface modified diamond layer 12, a source region 14, a gate region 16 and a drain region 18. Device 10 illustrates the principle of using surface modified diamond in a field effect transistor in which the diamond material 12 provides a hole conductivity channel between the source region 14 and the drain region 18 that is activated by a voltage applied to the intermediate gate region 16. In other devices it can be desirable to dope all or part of the diamond material, e.g., with a suitable dopant such as phosphorus or boron.

FIG. 3 is a graph of surface resistance versus time (minutes) for a diamond surface treated with a radical generator according to the invention and comparative data for a diamond surface treated by a conventional NO₂ approach.

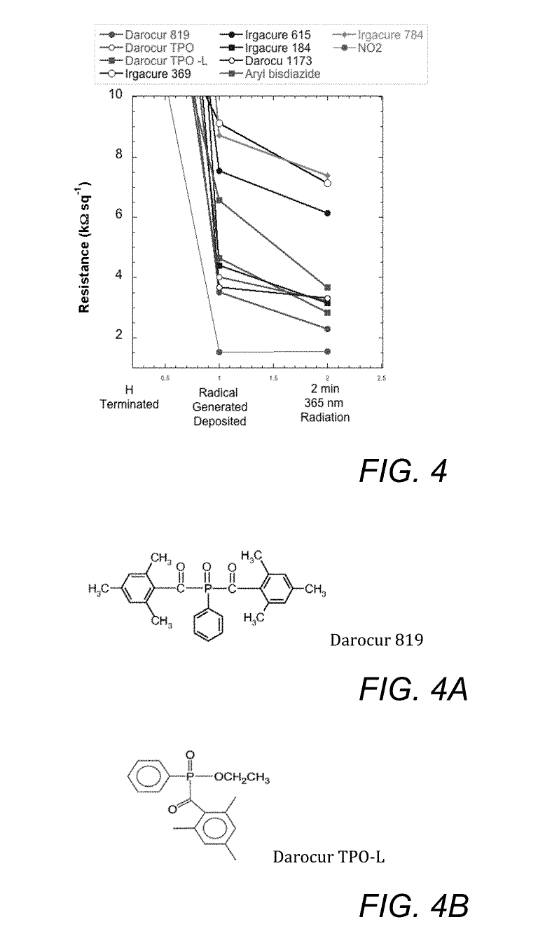

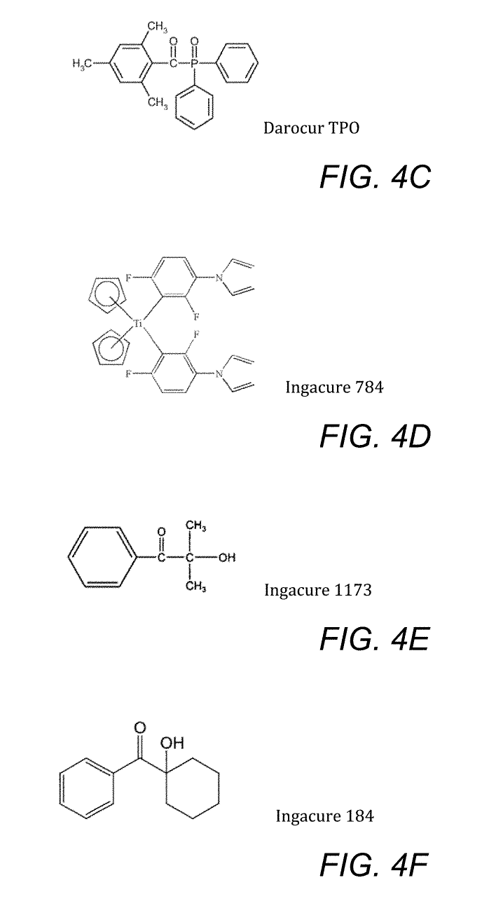

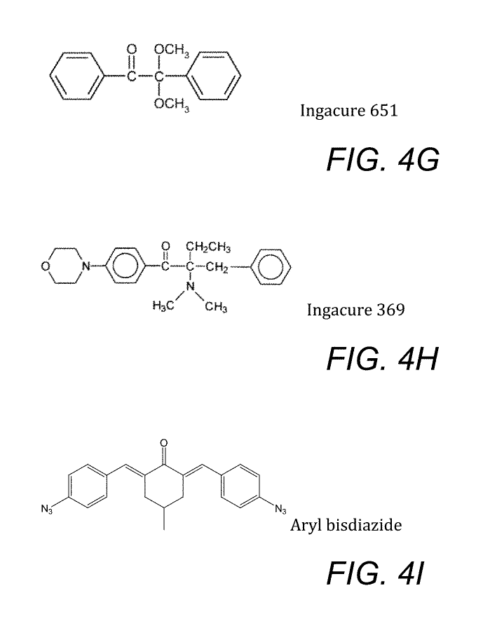

FIG. 4 is a graph of surface resistance versus time (days) for a diamond surface treated with various radical generators according to the invention demonstrating stability over time.

FIGS. 4A-4I illustrate chemical structures of various radical generators useful in the present invention (FIG. 4A: Darocur® 819; FIG. 4B: Darocur® TPO-L; FIG. 4C: Darocur®; FIG. 4D: Ingacure® 784; FIG. 4E: Ingacure® 1173; FIG. 4F: Ingacure ® 184; FIG. 4G: Ingacure® 651; FIG. 4H: Ingacure® 369; and FIG. 4I Aryl bisdiazide).

FIG. 5A is a depiction of a laser or optical beam exposing the surface of a diamond FET. The optical power is reduced as the beam approaches the gate, thereby producing a non-uniform density of surface modification and attached charge.

FIG. 5B illustrates how mobile holes in the diamond are attracted to (and can be formed by) the formed modification on the diamond surface, thereby making a conducting FET channel. As drain resistance is less important than source resistance, the surface modification to give charge groups on the drain side may be uniform if desired.

FIG. 5C illustrates that the charge groups can be formed non-uniformly on the drain side as well, which optimizes the drain resistance.

### EXAMPLES

### Materials:

2,6-Bis-(4-azido-benzylidene)-4-methyl-cyclohexanone (ABD) was supplied by TCI Chemicals. 1-Hydroxycyclohexyl phenyl ketone (Irgacure 184), 2-Benzyl-2-dimethylamino-1-(4-morpholinophenyl)-butanone-1 (Irgacure 369), cyclopenta-1,3-diene; 1-(2,4-difluorocyclohexa-2,3,5-trien-1-yl)pyrrole;titanium (Irgacure 784), bis(2,4,6-trimethylbenzoyl)-phenylphosphineoxide (Irgacure 819), 2-Hydroxy-2-methyl-1-phenyl-propan-1-one (Darocure 1173), 2,4,6-trimethylbenzoyl-diphenyl-phosphineoxide (Darocur TPO), and ethyl (2,4,6-trimethylbenzoyl) phenylphosphinate (Darocur TPO-L) were supplied by Ciba. Carbon tetrachloride (CCl₄) was supplied by Aldrich. Toluene (9466) and Acetone (9005) were purchased from Avantor, Inc. Tetrahydrofuran (34865) and Benzoyl Peroxide (179981) purchased from Sigma-Aldrich. Diamond 500 nm particles were received from Tomei Diamond Company. Single crystal diamonds were obtained from Element 6. The single crystal diamonds were made plasma epi and were cut a polished to 7×7 mm by about 100 um thick plate.

### Preparation of Hydrogen Terminated Diamond

Diamonds were terminated in a hydrogen/oxygen plasma (0.2% O₂ in H₂) for 30 minute at ˜800° C. and a pressure of 8 kPa. The diamond was heated from room temperature to 800° C. by a 100% H plasma whose RF power was slowly increase over a ˜10 min period. The same procedure in reverse was used to cool the diamond from 800° C. to room temperature. Both single crystal diamond and diamond particles were treated by the same hydrogenation process.

### Example 1

### Photo-Radical Generation in Carbon Tetrachloride with Oxygen

The single crystal diamond was submerged a solution of CCl₄ in which the light sensitive photo-radical generation compound (PRGC) was dissolved at a weigh percent of 0.67%. Prior to the placement of the diamond in the solution oxygen was bubbled through it. A mercury lamp filtered to only pass I line, 365 nm, was used to generate the radicals. The optical flux at the diamond surface was ˜0.6 mW cm⁻². Probes were attached to the diamond to measure its resistance during UV-radical exposure. The resistance change saturated in 5 to 10 minutes after which the diamond was removed rinsed in CCl₄, blown dry, and additional characterization was performed. For comparison, the process was also performed in CCl₄ in the absence of any PRGC.

TABLE 1
Summary of results from photo-radical generation in CCl₄ with
bubbled O₂.

| | | Resistance | Carrier | Mobility | |
|---|---|---|---|---|---|
| ID | Material | (kΩ/Square) | Density (cm⁻²) | (cm2/Vs) | TBD |
| 5 | Irgacure 819 | 2.1 | — | — | |

### Example 2

### Photo-Radical Generation in Carbon Tetrachloride with Nitrogen

Several procedures were used to generate photo-radicals to react with the diamond surface. In one technique the single crystal diamond was submerged a solution of CCl₄ in which the light sensitive photo-radical generation compound (PRGC) was dissolved at a weigh percent of 0.67%. Prior to the placement of the diamond in the solution high purity nitrogen was bubbled through it. A Hg lamp filtered to only pass I line, 365 nm, was used to generate the radicals. The optical flux at the diamond surface was ˜0.6 mW cm⁻² at the diamond surface. Probes were attached to the diamond to measure its resistance during UV-radical exposure. The resistance change saturated in 5 to 10 minutes after which the diamond was removed rinsed in CCl₄, blown dry, and additional characterization was performed.

TABLE 2
Summary of results from photo-radical generation in CCl₄ with
bubbled N₂.

| | | Resistance | Carrier | Mobility | |
|---|---|---|---|---|---|
| ID | Material | (kΩ/Square) | Density (cm⁻²) | (cm2/Vs) | TBD |
| 5 | Irgacure 819 | 2.8 | — | — | |

### Example 3

### Photo-Radical Generation in a Dry Film with Oxygen

A 67% solution of the PRGC in CCl₄ was prepared and was deposited on the single crystal diamond. The solvent was allowed to air dry leaving a film of solid the PRGC. The film was thin enough that it represented no optical barrier to the radiation passing through it to the diamond-PRGC interface. A Hg lamp filtered to only pass I line, 365 nm, was used to generate the radicals. The optical flux at the diamond surface was ˜0.6 mW cm⁻² at the diamond surface. The UV exposures were performed in oxygen. Diamonds were exposed until their resistance stabilized, typically 1 to 2 min, after which the diamond were further characterized. For comparison, the process was also performed by allowing CCl₄ in the absence of any PRGC to dry on the diamond surface.

TABLE 3
Summary of results from photo-radical generation in air using dry film technique in O₂.

| | | | | | Life Time of |
|---|---|---|---|---|---|
| | | Resistance | Carrier | Mobility | Resistance <4 kΩ/ |
| ID | Material | (kΩ/Square) | Density (cm⁻²) | (cm2/Vs) | Square |
| 1 | Irgacure 184 | 3.10 | 3.43 × 10¹³ | 57 | |
| 2 | Irgacure 369 | 8.62 | 7.32 × 10¹² | 98.8 | |
| 3 | Irgacure 651 | 6.14 | 3.34 × 10¹³ | 30 | |
| 4 | Irgacure 784 | 9.02 | 1.7 × 10¹³ | 40 | |
| 5 | Irgacure 819 | 2.29 | 4.13 × 10¹³ | 66 | >7 days |
| 6 | Darocur 1173 | 3.31 | 2.87 × 10¹³ | 65 | |
| 7 | Darocur TPO | 3.21 | 1.4 × 10¹³ | 131 | |
| 8 | Darocur TPO-L | 2.84 | 3.13 × 10¹³ | 70 | |
| 9 | ABD | 3.67 | 2.06 × 10¹³ | 82.5 | |
| 10 | CCl₄ | 15.4 | 6.82 × 10¹² | 59.4 | |

### Example 4

### Photo-Radical Generation in a Dry Film with Nitrogen

A 67% solution of the PRGC in CCl₄ was prepared and was deposited on the single crystal diamond. The solvent was allowed to air dry leaving a film of solid the PRGC. The film was thin enough that it represented no optical barrier to the radiation passing through it to the diamond-PRGC interface. A Hg lamp filtered to only pass I line, 365 nm, was used to generate the radicals. The optical flux at the diamond surface was ˜0.6 mW cm⁻² at the diamond surface. The UV exposures were performed in nitrogen. Diamonds were exposed until their resistance stabilized, typically 1 to 2 min, after which the diamond were further characterized.

TABLE 4
Summary of photo-radical generation in air using the dry film
technique in N₂.

| | | Resistance | Carrier | Mobility | |
|---|---|---|---|---|---|
| ID | Material | (kΩ/Square) | Density (cm⁻²) | (cm2/Vs) | TBD |
| 5 | Irgacure 819 | 4.18 | 3.23 × 10¹³ | 46.2 | |

### Example 5

### Comparative Examples of Other Surface Modifying Processes

NO₂ for surface modification of diamond was generated by reacting copper turnings with concentrated nitric acid. The single crystal diamond was exposed to NO₂ for 1 min. The sample resistance usually saturated in the first 10 s of exposure. The resistance increases rapidly over time to reach 6 kΩ/Square after 2 days. This stability is poor leading to a resistance that is unacceptability high. Similar resistances and increase in resistance with time using NO₂ treated diamond by Michal Kubovic, et al., “Sorption properties of NO2 gas and its strong influence on hole concentration of H-terminated diamond surfaces,” Applied Physics Letters 96, 052101 (2010).

The reported results in Table 5 using Al₂O₃ was obtained by depositing Al₂O₃ on the diamond by an atomic layer deposition (ALD) system at 400° C. After deposition the diamond-Al₂O₃ sample was exposed to NO₂ as previously discussed. The resistance of 5 kΩ/Square is unacceptability high. Similar results (˜5 kΩ/Square) with NO₂ and ALD deposited Al₂O₃ have been reported by Kazuyuki Hirama, et al., “Thermally Stable Operation of H-Terminated Diamond FETs by NO2 Adsorption and Al2O3 Passivation,” IEEE Electron Device Letters 33 (8) 1111-1113 (2012).

TABLE 5
Summary of comparative examples of other surface modifying processes

| | | | | Life Time of | |
|---|---|---|---|---|---|
| | | | | Resistance | |
| | | Resistance | | <4 kΩ/ | |
| ID | Material | (kΩ/Square) | Comments | Square | Reference |
| 10 | NO₂ | 1.5 | Quickly | ~1 day | Lincoln |
| | | | degrades in lab | environment | |
| | | | air | dependent | |
| 11 | Al₂O₃ and | 5 | | | Lincoln |
| | NO₂ | | | | |

### Example 6

### Photo- and Thermal Radical Treatment of Diamond Powders

Reactions were run on hydrogenated 500 nm diamond particles, using either Darocur 1173, Irgacure 819 or Benzoyl Peroxide as radical generators, in THF, Acetone, or toluene as solvents. Null Experiments were also run without any radical generator. See Table 6 for a full list of experimental combinations run. In all reactions, 100 mg diamond was mixed into 30 mL of solvent in a three-neck flask. The mixture was then sonicated for 30 minutes to disperse the particles. 50 mg of the radical generator was then added. The dispersion was then purged by bubbling argon through it for 15 minutes to de-gas the reaction contents.

For experiments using the photoradical generators, Irgacure 819 and Darocur 1173, the flask was then positioned at a distance of 2 cm from the ultraviolet source lamp, which gave an intensity of 4.5 mW/cm² at a wavelength of 365 nm. Argon gas was continuously bubbled into the reaction contents during UV exposure. Experiments using Irgacure 819 were exposed for 1 hour and experiments using Darocur 1173 were exposed for 5 hours.

For experiments using the thermos-radical generator, benzoyl peroxide, the flask was heated at 75° C. for 1 hour. Argon gas was continuously bubbled into the reaction contents during heating. After exposure/heating the reaction contents were centrifuged at 4000 RPM for 20 minutes and the supernatant was poured off to remove the excess radical generators with the solvent. The samples were then each rinsed and centrifuged twice more in their respective solvents before being placed under vacuum at 50° C. overnight to dry.

TABLE 6
Reaction Conditions for treatment of diamond powders

| | | | | Energy | Exposure |
|---|---|---|---|---|---|
| ID | Diamond | Solvent | Radical Generator | Input | Length (h) |
| 12 | Hydrogenated | THF | Irgacure 819 | UV | 1 |
| 13 | Hydrogenated | Acetone | Irgacure 819 | UV | 1 |
| 14 | Hydrogenated | THF | Darocur 1173 | UV | 5 |
| 15 | Hydrogenated | Acetone | Darocur 1173 | UV | 5 |
| 16 | Hydrogenated | Toluene | Benzoyl Peroxide | Heat | 1 |
| 17 | Hydrogenated | Toluene | None | Heat | 1 |
| 18 | Hydrogenated | THF | None | UV | 1 |

The surface of the diamond particles was then characterized using diffuse reflectance FTIR on a Bruker Vertex 70 FTIR spectrometer. For measurement, the IR source was positioned at a 45° angle in a Harrick Seagull accessory. A summary of the FTIR results is shown in Table 7. The spectra of all samples showed no measurable addition of carbonyl or methyl groups. UV-exposed samples of hydrogenated diamond showed effective removal of all hydrogen on the diamond surface, even as compared to the original non-hydrogenated diamond. Sample 19 shows the FTIR measurement of the Diamond 500 nm particles as received from Tomei Diamond Company and Sample 20 shows the FTIR measurement of the Diamond 500 nm particles after hydrogenation. The % surface hydrogenation is the normalized degree of surface hydrogenation as determined by the integration of carbon-hydrogen IR stretches associated with methane diamond surface hydrogens.

TABLE 7
FTIR results from treatment of diamond powders

| | | % Surface | | |
|---|---|---|---|---|
| Sample | Diamond | Hydrogen | Carbonyl | CH₃ |
| 12 | Hydrogenated | 5.7 | No | No |
| 13 | Hydrogenated | 0.4 | No | No |
| 14 | Hydrogenated | 15.1 | No | No |
| 15 | Hydrogenated | 6.4 | No | No |
| 16 | Hydrogenated | 30.0 | No | No |
| 17 | Hydrogenated | 9.8 | No | No |
| 18 | Hydrogenated | 41.8 | No | No |
| 19 | As Received | 14.0 | No | No |
| 20 | Hydrogenated | 100.0 | No | No |

The results show that all conditions reduce the degree of surface hydrogenation and that several conditions reduce the degree of surface hydrogenation by greater than 90% indicating that significant amounts of surface hydrogen was lost. In none of the conditions did surface carbonyl or methyl grounds appear, indicating that surface addition of the organic radical special did not occur.

All patent documents and publications mentioned herein are likewise incorporated herein by reference in their entirety.

Those having ordinary skill in the art will appreciate that various changes can be made to the above embodiments without departing from the scope of the invention. All numerical ranges recited herein are intended to include all sub-ranges and individual values within such ranges.

1. A diamond material suitable for use in semiconductor devices derived by treating a hydrogenated diamond surface such that it exhibits a stable surface resistance below about 3 kΩ sq⁻¹.

2. The diamond material of claim 1 wherein the material is a epitaxial layer grown on a substrate.

3. The diamond material of claim 1 wherein the material is a epitaxial layer having a thickness ranging from 1 nm to 1 mm, or optionally 10 nm to 10 μm.

4. The diamond material of claim 1 wherein the material is a epitaxial layer grown by microwave plasma chemical vapor deposition (CVD).

5. The diamond material of claim 1 wherein some portion of the hydrogenated diamond surface exhibits a loss of hydrogen atoms.

6. The diamond material of claim 1 wherein the surface is further characterized by double bonds between superficial carbon atoms.

7. The diamond material of claim 6 wherein double bonds are formed by exposure to a chemically-active radical.

8. The diamond material of claim 1 wherein double bonds are formed by exposure to photo-radical or thermal-radical generator.

9. The diamond material of claim 1 wherein the diamond material has at least a portion of its surface activated by incorporation of a surface-modifying radical.

10. The diamond material of claim 8 wherein the surface-modifying radical is an organic radical.

11. The diamond material of claim 8 wherein the surface-modifying radical is an alkyl or aromatic radical

12. The diamond material of claim 1 wherein the surface-modifying radical is selected from the group of benzoyl radicals and phosphineoxide radicals.

13. The diamond material of claim 1 wherein the surface-modifying radical forms an amine on the diamond surface.

14. A semiconductor device incorporating the diamond material of claim 1.

15. The semiconductor device of claim 14 wherein the device is a field effect transistor in which the diamond material provides a hole conductivity channel between a source region and a drain region that is activated by a voltage applied to an intermediate gate region.

16. The semiconductor device of claim 15 wherein the diamond material exhibits a gradation of surface resistance.

17. A method of modifying a hydrogenated surface of a diamond material comprising treating the hydrogenated diamond surface with a chemically active radical to remove hydrogen atoms and form a negatively charged surface.

18. The method of claim 17 wherein the method further comprises terminating the diamond surface with hydrogen prior to treating the surface with a chemical radical.

19. The method of claim 17 wherein the surface-modifying radical induces an elimination reaction to remove at least some hydrogen atoms at the surface.

20. The method of claim 17 wherein the surface-modifying radical induces formation of double-bonds between superficial carbon atoms in the diamond material.

21. The method of claim 20 wherein the double bonds form fullerene-like structures at the surface.

22. The method of claim 17 wherein the method further comprises modifying the surface of the diamond material by incorporating the chemical-active radical onto at least a portion of the diamond surface.

23. The method of claim 22 wherein the surface-modifying radical is an organic radical.

24. The method of claim 22 wherein the surface-modifying radical is an alkyl or aromatic radical

25. The method of claim 22 wherein the surface-modifying radical is selected from the group of benzoyl radicals and phosphineoxide radicals.

26. The method of claim 22 wherein the surface-modifying radical forms an amine on the diamond surface.

27. The method of claim 17 wherein the diamond surface attracts positive charges below the surface of the diamond material.

28. The method of claim 17 wherein the method further comprises modifying the diamond surface with a radical by applying a radical generator to the surface following hydrogen termination.

29. The method of claim 28 wherein the radical generator is a photo-radical generator.

30. The method of claim 28 wherein the radical generator is a thermal radical generator.

31. The method of claim 28 wherein the method further comprises exposing the radical generator to heat following application of the radical generator to the hydrogen-terminated, diamond surface.

32. The method of claim 28 wherein the method further comprises exposing the radical generator to actinic radiation following application of the radical generator to the hydrogen-terminated, diamond surface.

33. The method of claim 32 wherein the method further comprises selectively exposing portions of the surface to actinic radiation following application of the radical generator to the surface.

34. The method of claim 32 wherein the method further comprises exposing the radical generator to actinic radiation having at least one wavelength in the range between 150 and 800 nm.

35. The method of claim 32 wherein the method further comprises exposing the radical generator to actinic radiation having at least one wavelength in the range between 150 and 450 nm.

36. The method of claim 35 wherein the at least one wavelength is a wavelength selected from 157, 193, 248, 256, 365, 405, and 436 nms.
